(19) United States
(12) Patent Application Publication
(10) Pub. No.: US 2026/0059685 A1
(43) Pub. Date: Feb. 26, 2026

(54) ELECTRONIC DEVICE AND ELECTRONIC APPARATUS

(71) Applicant: Wiwynn Corporation, New Taipei City (TW)

(72) Inventors: Nicholas Chang, New Taipei City (TW); Chi-Luen Chen, New Taipei City (TW); Shih-Hung Chen, New Taipei City (TW); Ming-Chih Kao, New Taipei City (TW)

(73) Assignee: Wiwynn Corporation, New Taipei City (TW)

(21) Appl. No.: 19/214,059

(22) Filed: May 21, 2025

Related U.S. Application Data
(60) Provisional application No. 63/684,871, filed on Aug. 20, 2024.

(30) Foreign Application Priority Data
Dec. 4, 2024 (TW) 113146924

(51) Int. Cl. H05K 7/14

(52) U.S. Cl. CPC H05K 7/1487

(57) ABSTRACT

An electronic device includes a housing and two electronic modules. The housing has an accommodation space. The accommodation space has a first cross-sectional shape perpendicular to a first direction. The two electronic modules are disposed in the accommodation space. Each of the electronic modules has a concave-convex surface. The concave-convex surfaces of the two electronic modules are arranged oppositely and cooperate with each other, so that the two electronic modules together form a second cross-sectional shape perpendicular to the first direction, and the second cross-sectional shape matches the first cross-sectional shape.

### CROSS REFERENCE TO RELATED APPLICATIONS

This application claims the benefit of U.S. Provisional Application No. 63/684,871, filed on Aug. 20th, 2024. The content of the application is incorporated herein by reference.

### BACKGROUND OF THE INVENTION

### 1. Field of the Invention

The present disclosure relates to an electronic device and an electronic apparatus, and more particularly, to an electronic device which is beneficial to improve space utilization efficiency and an electronic apparatus including the same.

### 2. Description of the Prior Art

With the vigorous development of cutting-edge technologies, such as Internet of Things, edge computing and artificial intelligence, electronic device with a huge information processing capability plays an indispensable role. In general, a plurality of different and/or identical electronic components can be installed in a housing of an electronic device to achieve the desired functions. Taking a server as an example, different electronic components, such as motherboards, central processing units (CPU), memories, chips, hard disk, network cards, power supplies and fans, are disposed in a housing of the server to provide specific function to meet the needs of users. Therefore, how to improve the space utilization efficiency of the electronic device to allow the electronic device to provide more powerful computing power and load a larger amount of storage data has become a goal of relevant industry.

### SUMMARY OF THE INVENTION

According to an embodiment of the present disclosure, an electronic device includes a housing and two electronic modules. The housing has an accommodation space. The accommodation space has a first cross-sectional shape perpendicular to a first direction. The two electronic modules are disposed in the accommodation space. Each of the electronic modules has a concave-convex surface. The concave-convex surfaces of the two electronic modules are arranged oppositely and cooperate with each other, so that the two electronic modules together form a second cross-sectional shape perpendicular to the first direction, and the second cross-sectional shape matches the first cross-sectional shape.

According to another embodiment of the present disclosure, an electronic apparatus includes the aforementioned electronic device and an installation unit. The electronic device is detachably installed in the installation unit.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic view showing an appearance of an electronic device according to an embodiment of the present disclosure.

FIG. 2 is a schematic plane view of the electronic device in FIG. 1.

FIG. 3 is an exploded schematic view of the electronic device in FIG. 1.

FIG. 4 is a schematic view showing an electronic module solely pulled out from a housing of the electronic device in FIG. 1.

FIG. 5 is a schematic cross-sectional view of the electronic device in FIG. 2 taken along line A-A′.

FIG. 6 is a schematic view showing positions of a center of gravity of the electronic device and centers of gravity and of the two electronic modules in FIG. 1

FIG. 7 is a schematic view showing of a gravity and a hanging force on the electronic device in FIG. 1.

FIG. 8 is a schematic view showing an appearance of an electronic apparatus according to an embodiment of the present disclosure.

FIG. 9 is a schematic view showing an appearance of an electronic apparatus according to another embodiment of the present disclosure.

### DETAILED DESCRIPTION

In the following detailed description of the embodiments, reference is made to the accompanying drawings which form a part thereof, and in which is shown by way of illustration specific embodiments in which the disclosure may be practiced. In this regard, directional terminology, such as up, down, left, right, front, back, bottom or top is used with reference to the orientation of the Figure(s) being described. The elements of the present disclosure can be positioned in a number of different orientations. As such, the directional terminology is used for purposes of illustration and is in no way limiting. In addition, identical numeral references or similar numeral references are used for identical elements or similar elements in the following embodiments.

Hereinafter, for the description of “the first feature is formed on or above the second feature”, it may refer that “the first feature is in contact with the second feature directly”, or it may refer that “there is another feature between the first feature and the second feature”, such that the first feature is not in contact with the second feature directly.

It is understood that, although the terms first, second, etc. may be used herein to describe various elements, regions, layers and/or sections, these elements, regions, layers and/or sections should not be limited by these terms. These terms may be only used to distinguish one element, region, layer and/or section from another element, region, layer and/or section. Terms such as “first,” “second,” and other numerical terms when used herein do not imply a sequence or order unless clearly indicated by the context. Thus, a first element, region, layer and/or section discussed below could be termed a second element, region, layer and/or section without departing from the teachings of the embodiments. The terms used in the claims may not be identical with the terms used in the specification, but may be used according to the order of the elements claimed in the claims.

In the present disclosure, when any two numerical values or features (such as shapes) used for comparison are “substantially” the same, which may refer that there may have an error or difference between the two numerical values or features used for comparison. For example, there may be an error or difference within 10% between the two numerical values or features (when quantifiable), and the error or difference may be caused by differences in tolerances of different components and/or assembly clearances.

In the present disclosure, some of the following drawings are described in conjunction with the XYZ Cartesian coordinate system for the sake of convenience. In the following description, the first direction is exemplified by parallel to the direction Z, the second direction is exemplified by parallel to the direction X, and the third direction is exemplified by parallel to the direction Y. The second direction and the third direction may be located on a same plane (herein, exemplified by a plane parallel to X-Y plane), the second direction and the third direction may be perpendicular to each other, and the first direction may be parallel to a normal direction of the aforementioned plane.

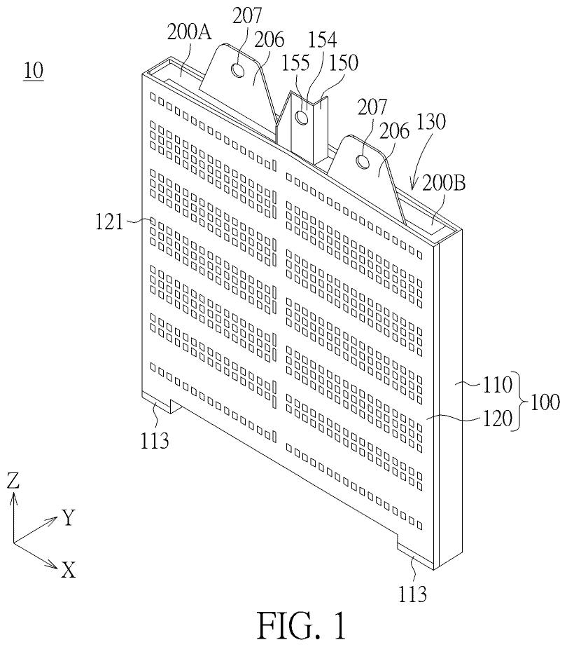

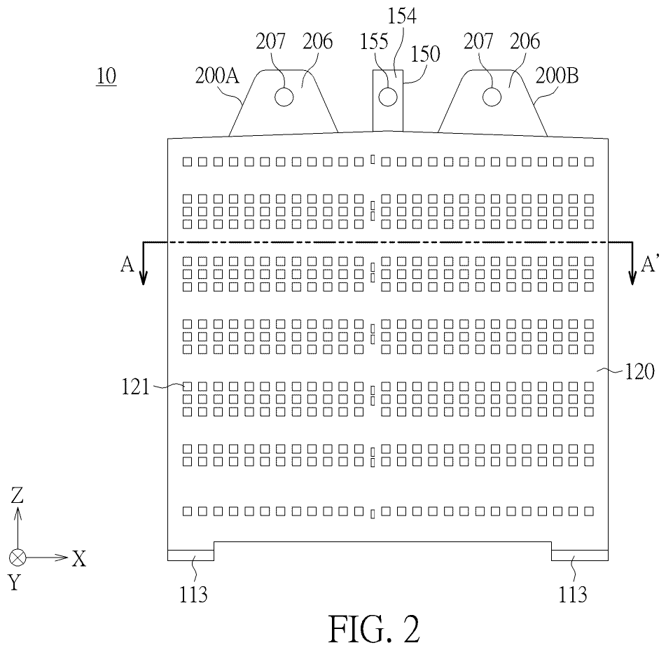

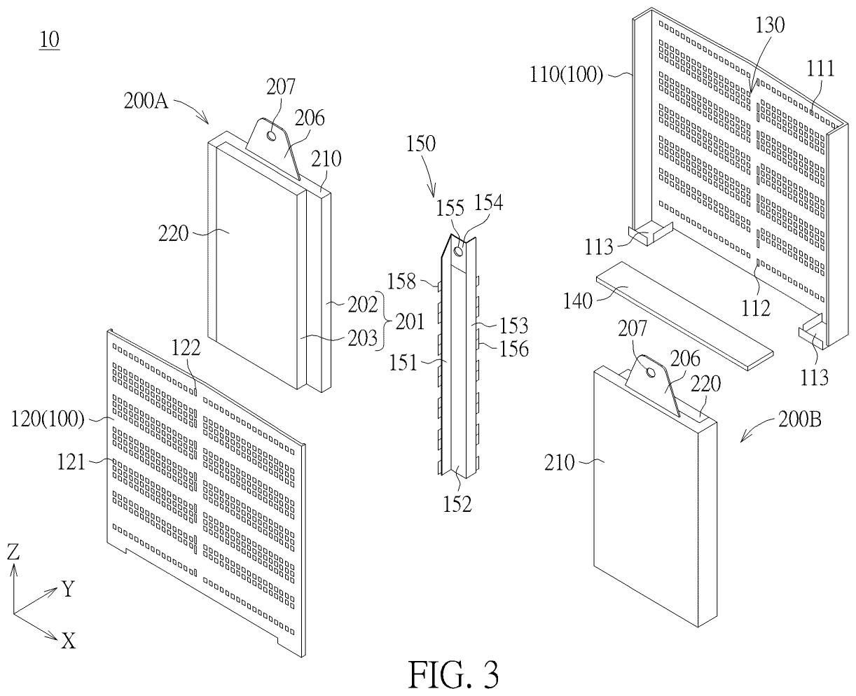

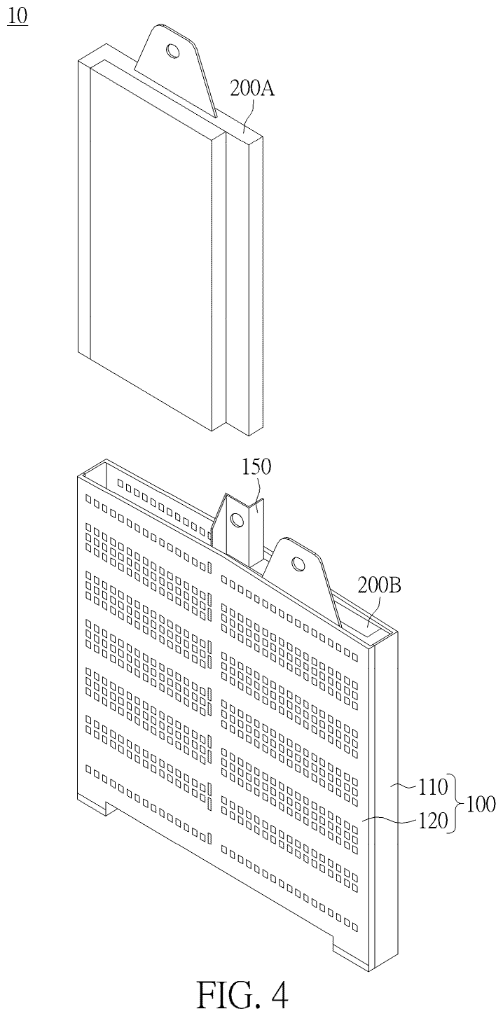

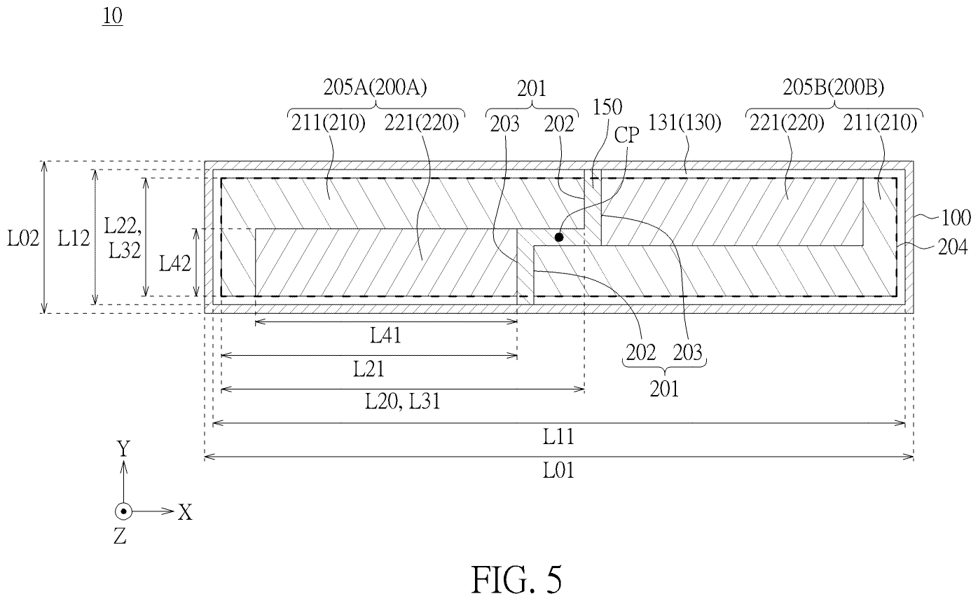

Please refer to FIG. 1 and FIG. 5. FIG. 1 is a schematic view showing an appearance of an electronic device 10 according to an embodiment of the present disclosure. FIG. 2 is a schematic plane view of the electronic device 10 in FIG. 1. FIG. 3 is an exploded schematic view of the electronic device 10 in FIG. 1. FIG. 4 is a schematic view showing an electronic module 200A solely pulled out from a housing 100 of the electronic device 10 in FIG. 1. FIG. 5 is a schematic cross-sectional view of the electronic device 10 in FIG. 2 taken along line A-A′. The electronic device 10 includes a housing 100 and two electronic modules 200A and 200B. The housing 100 has an accommodation space 130. As shown in FIG. 5, the accommodation space 130 has a first cross-sectional shape 131 perpendicular to the first direction (the first direction being parallel to the direction Z). The two electronic modules 200A and 200B are disposed in the accommodation space 130. Each of the electronic modules 200A and 200B has a concave-convex surface 201. The concave-convex surfaces 201 of the two electronic modules 200A and 200B are arranged oppositely and cooperate with each other, so that the two electronic modules 200A and 200B together form a second cross-sectional shape 204 perpendicular to the first direction. In FIG. 5, the second cross-sectional shape 204 is a shape shown by the dotted line. The second cross-sectional shape 204 matches or fits the first cross-sectional shape 131. Thereby, when viewing the electronic device 10 along the first direction, the outline of the assembled electronic modules 200A and 200B (i.e., the outline of the second cross-sectional shape 204) matches the shape of the accommodation space 130 (i.e., the first cross-sectional shape 131). It is beneficial to make full use of the accommodation space 130 of the housing 100, so as to improve the space utilization efficiency of the electronic device 10.

Specifically, as shown in FIG. 3, the housing 100 may optionally include a first housing part 110, a second housing part 120 and a power supply base 140. The first housing part 110 may include at least one heat dissipation hole 111, at least one mounting hole 112 and two supporting portions 113. The second housing part 120 may include at least one heat dissipation hole 121 and at least one mounting hole 122. The first housing part 110 and the second housing part 120 may be assembled with each other to define the accommodation space 130 between the first housing part 110 and the second housing part 120. The support portions 113 are located at one end of the housing 100 (herein, the lower end). The support portions 113 may have flat outer surfaces. Thereby, it is beneficial for the electronic device 10 being placed vertically through the support portions 113. Herein, the electronic device 10 being placed vertically may refer that an opening of the housing 100 faces upward.

The power supply base 140 is disposed below the accommodation space 130. The power supply base 140 may include circuit components (not shown), such as bus bars and conductive terminals, to be electrically connected to the electronic modules 200A and 200B, so that the electronic modules 200A and 200B can be electrically connected to each other or electrically connected to external power units (not shown) or other electronic units (not shown).

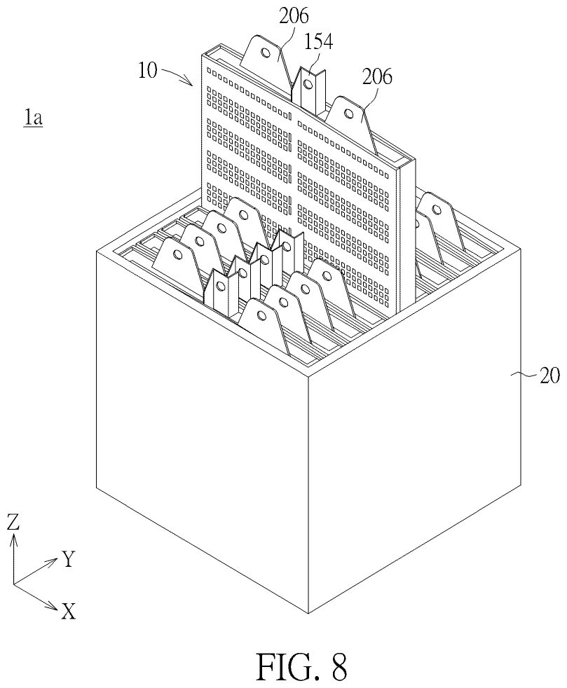

As shown in FIG. 4, each of the electronic modules 200A and 200B is detachably installed in the accommodation space 130 along the first direction. The electronic device 10 may further include a partition 150. The partition 150 is fixed to the housing 100 and is disposed between the concave-convex surfaces 201 of the two electronic modules 200A and 200B. With the partition 150, the accommodation space 130 can be further divided into two sub-spaces (not labeled) for respectively accommodating the electronic module 200A and the electronic module 200B, so that the electronic modules 200A and 200B can be independently moved in or moved out the accommodation space 130, which is beneficial to simplify the maintenance process of the electronic modules 200A and 200B. For this part, references may be made to the relevant description in FIG. 8.

In FIG. 3, the partition 150 may include a first sheet body 151, a second sheet body 152 and a third sheet body 153 connected in sequence, and the first sheet body 151 and the third sheet body 153 respectively correspond to the convex portion 202 and the concave portion 203 of the concave-convex surface 201 of one of the electronic modules 200A and 200B, and the first sheet body 151 and the third sheet body 153 are bent relative to the second sheet body 152. Herein, the first sheet body 151 corresponds to the concave portion 203 of the electronic module 200A and the convex portion 202 of the electronic module 200B, and the third sheet body 153 corresponds to the convex portion 202 of the electronic module 200A and the concave portion 203 of the electronic module 200B. Thereby, the partition 150 is bent according to the concave-convex surfaces 201 of the two electronic modules 200A and 200B, which is beneficial for the two electronic modules 200A and 200B to fit with each other through the partition 150, so as to make full use of the accommodation space 130 of the housing 100. The partition 150 may include at least one mounting portion 156 corresponding to the mounting hole 112 of the first housing part 110 and at least one mounting portion 158 corresponding to the mounting hole 122 of the second housing part 120. Thereby, the mounting portions 156 and 158 can be respectively embedded in the mounting holes 112 and 122, and the partition 150 can be fixed to the housing 100. It should be noted that, for the convenience of explanation, the ratio of the size of the partition 150 to the size of each of the two electronic modules 200A and 200B is exaggerated in the drawings. In the present disclosure, the size of the partition 150 is not limited by the ratio shown in the drawings.

The partition 150 may further include a hanging portion 154 extending to an outside of the accommodation space 130. The hanging portion 154 may be formed with a hanging hole 155. With the hanging portion 154, the force application point for hanging and clamping the electronic device 10 can be provided, which is beneficial for the maintenance personnel to move the electronic device 10 through the hanging portion 154.

The electronic module 200A and the electronic module 200B may be two identical electronic modules which may have the same design and component layout, and are given different reference signs for the sake of convenience for explanation. Each of electronic modules 200A and 200B includes a first electronic component 210 and a second electronic component 220 respectively corresponding to the convex portion 202 and the concave portion 203 of the concave-convex surface 201.

For example, the electronic device 10 may be a server, and the first electronic component 210 and the second electronic component 220 may be components of the server. For example, the first electronic component 210 may be a graphics processing substrate, which may include a circuit board and a graphics processing unit (GPU) disposed thereon. The second electronic component 220 may be a server motherboard, which may include a circuit board and electronic components disposed thereon, such as central processing units (CPU), memories, Ethernet ports, fans, hard disks and/or other components of a typical computer, so that the electronic modules 200A and 200B including the first electronic component 210 and the second electronic component 220 can achieve the functions of a computer. Therefore, each of the electronic modules 200A and 200B may be regarded as a computer. Each of the electronic modules 200A and 200B may also be called a node. The nodes can communicate with each other through one or more buses, computer networks or other computer communication means.

Each of the electronic modules 200A and 200B may further include a hanging portion 206 extending to an outside of the accommodation space 130. The hanging portion 206 may be formed with a hanging hole 207. With the hanging portions 206, the force application points for hanging and clamping the electronic modules 200A and 200B can be provided, which is beneficial for maintenance personnel to move the electronic modules 200A and 200B through the hanging portions 206.

In FIG. 5, the first electronic component 210 includes a cross-sectional shape 211 perpendicular to the first direction, the second electronic component 220 includes a cross-sectional shape 221 perpendicular to the first direction, the electronic module 200A includes a third cross-sectional shape 205A perpendicular to the first direction, and the electronic module 200B includes a third cross-sectional shape 205B perpendicular to the first direction. The cross-sectional shape 211 is formed in an L shape and is an asymmetric shape. The cross-sectional shape 221 is formed in a rectangle and is a symmetrical shape. The third cross-sectional shape 205A and the third cross-sectional shape 205B are formed in the same shape and both are asymmetric shapes. In other words, at least one of the first electronic component 210 and the second electronic component 220 has an asymmetric shape, so that the electronic modules 200A and 200B assembled by the first electronic component 210 and the second electronic component 220 also include asymmetrical shapes. It should be noted that although the third cross-sectional shape 205A and the third cross-sectional shape 205B of the electronic modules 200A and 200B include asymmetric shapes, as shown in FIG. 5, the third cross-sectional shape 205A (electronic module 200A) and the third cross-sectional shape 205B (electronic module 200B) are symmetric with each other relative to a center point CP. The arrangement of the third cross-sectional shape 205A (electronic module 200A) and the third cross-sectional shape 205B (electronic module 200B) shows point symmetry, also know as point reflection.

As shown in FIG. 5, the accommodation space 130 has a first cross-sectional shape 131, the two electronic modules 200A and 200B together form a second cross-sectional shape 204, and the second cross-sectional shape 204 matches the first cross-sectional shape 131. The aforementioned center point CP may be, for example, a center point of the first cross-sectional shape 131. The aforementioned “second cross-sectional shape 204” may refer to the shape defined by the outlines of the two electronic modules 200A and 200B with the concave-convex surfaces of the two electronic modules 200A and 200B being arranged oppositely and cooperating with each other. The aforementioned “the concave-convex surfaces of the two electronic modules 200A and 200B cooperating with each other” may refer that the concave-convex surfaces 201 of the two electronic modules 200A and 200B can be fitted with each other. The aforementioned being fitted with each other may be directly fitted with each other (that is, no other components are disposed between the concave-convex surfaces 201 of the two electronic modules 200A and 200B) or indirectly fitted with each other (that is, other components (hereinafter, intermediate components) are disposed between the concave-convex surfaces 201 of the two electronic modules 200A and 200B).

When no intermediate component is disposed between the concave-convex surfaces 201 of the two electronic modules 200A and 200B, the second cross-sectional shape 204 may be defined as consisting of the third cross-sectional shape 205A and the third cross-sectional shape 205B. When an intermediate component, such as the partition 150, is disposed between the concave-convex surfaces 201 of the two electronic modules 200A and 200B, the second cross-sectional shape 204 can be defined as consisting of the third cross-sectional shape 205A, at least a portion of the cross-sectional shape of intermediate component perpendicular to the first direction and the third cross-sectional shape 205B. The aforementioned “at least a portion of the cross-sectional shape of intermediate component perpendicular to the first direction” may refer the portion of the cross-sectional shape of intermediate component located within the outer boundaries of the third cross-sectional shape 205A and 205B, such as the portion of partition 150 located within the dotted line shown in FIG. 5. In some embodiments, when an intermediate component is disposed between the concave-convex surfaces 201 of the two electronic modules 200A and 200B, the second cross-sectional shape 204 may also be defined as only consisting of the third cross-sectional shape 205A and the third cross-sectional shape 205B. For example, when the thickness of the intermediate component is very thin, the influence of the intermediate component can be ignored.

The aforementioned “the second cross-sectional shape 204 matches the first cross-sectional shape 131” may refer that the second cross-sectional shape 204 matches the first cross-sectional shape 131 in shape and/or in area. Preferably, the second cross-sectional shape 204 matches the first cross-sectional shape 131 in both shape and area. Matching in shape may refer that the second cross-sectional shape 204 and the first cross-sectional shape 131 have substantially similar shapes. Taking FIG. 5 as an example, the second cross-sectional shape 204 is a rectangle, the first cross-sectional shape 131 is a rectangle, and the second cross-sectional shape 204 and the first cross-sectional shape 131 are similar rectangles, but not limited thereto. The second cross-sectional shape 204 and the first cross-sectional shape 131 may be arranged in other geometric shapes according to actual requirements, such as ellipses and squares.

Matching in area may refer that the area of the second cross-sectional shape 204 is substantially equal to the area of the first cross-sectional shape 131 or the area of the second cross-sectional shape 204 is slightly smaller than the area of the first cross-sectional shape 131, so that the second cross-sectional shape 204 can almost fill the all area of the first cross-sectional shape 131, while the two electronic modules 200A and 200B can be removably or detachably installed in the housing 100. Situations that the two electronic modules 200A and 200B tightly fit into the housing 100 and cannot be freely pulled out form the housing 100 due to the area of the second cross-sectional shape 204 being slightly larger than or just equal to the area of the first cross-sectional shape 131 can be prevented.

In FIG. 5, the housing 100 has a first length L01 in a second direction (herein, exemplified by the direction X) perpendicular to the first direction, the first cross-sectional shape 131 (or the accommodation space 130) has a first accommodation length L11 in the second direction, and the first length L01 is greater than the first accommodation length L11. Each of the electronic modules 200A and 200B has a first length L20 in the second direction. The first length L20 corresponds to the convex portion 202 of the concave-convex surface 201. Each of the electronic modules 200A and 200B has a second length L21 in the second direction. The second length L21 corresponds to the concave portion 203 of the concave-convex surface 201. The first length L20 may be greater than the second length L21. In addition, the first length L20 may be greater than a half of the first accommodation length L11, and the first length L20 may be less than the first accommodation length L11. The second length L21 may be greater than 0 and less than a half of the first accommodation length L11. The sum of the first length L20 and the second length L21 may match the first accommodation length L11. When no intermediate component is disposed between the concave-convex surfaces 201 of the two electronic modules 200A and 200B, the aforementioned “the sum of the first length L20 and the second length L21 may match the first accommodation length L11” may refer that the sum of the first length L20 and the second length L21 may be substantially equal to the first accommodation length L11. When the intermediate component is disposed between the concave-convex surfaces 201 of the two electronic modules 200A and 200B, the aforementioned “the sum of the first length L20 and the second length L21 may match the first accommodation length L11” may refer that the sum of the first length L20, a length of the portion of the intermediate component between the electronic modules 200A and 200B in the first direction and the second length L21 may be substantially equal to the first accommodation length L11.

The housing 100 has a second length L02 in a third direction (herein, exemplified by the direction Y) perpendicular to the first direction, the first cross-sectional shape 131 (or the accommodation space 130) has a second accommodation length L12 in the third direction. The second length L02 is greater than the second accommodation length L12. Each of the electronic modules 200A and 200B has a third length L22 in the third direction, and the third length L22 matches the second accommodation length L12. The aforementioned “the third length L22 matches the second accommodation length L12” may refer that the third length L22 is substantially equal to the second accommodation length L12. According to an embodiment of the present disclosure, the length L02 of the housing 100 in the third direction may be equal to two rack units (U).

The first length L31 of the first electronic component 210 in the second direction may be equal to the first length L20, and the first length L41 of the second electronic component 220 in the second direction may be less than the first length L20. In this case, the maximum length (i.e., the first length L20) of the electronic modules 200A and 200B in the second direction is defined by the first electronic component 210. The second length L32 of the first electronic component 210 in the third direction may be equal to the third length L22, and the second length L42 of the second electronic component 220 in the third direction may be less than the third length L22. In this case, the maximum length (i.e., the third length L22) of the electronic modules 200A and 200B in the third direction is defined by the first electronic component 210. In other words, when viewing the electronic device 10 along the first direction, the first electronic component 210 is the component with a larger length (i.e., the first length L31) and a larger width (i.e., the second length L32) in the electronic modules 200A and 200B.

Specifically, when the first length L31 of the first electronic component 210 is greater than a half of the first accommodation length L11, the electronic modules 200A and 200B cannot be placed side by side in the accommodation space 130 along the second direction with the same orientation. If the electronic modules 200A and 200B are desired to be arranged side by side in the same housing 100 along the second direction with the same orientation, the length L01 of the housing 100 in the second direction is required to be increased. That is, the design of the housing 100 is required to be changed to accommodate the two electronic modules 200A and 200B at the same time. In this case, since the first length L31 of the first electronic component 210 is different from the first length L41 of the second electronic component 220, part of the accommodation space 130 is not occupied by the first electronic component 210 and the second electronic component 220. Thereby, the space utilization efficiency is poor. If the length L01 of the housing 100 in the second direction is not increased, and the first electronic component 210 and the second electronic component 220 are arranged side by side in the accommodation space 130 along the second direction, the remaining space cannot accommodate another first electronic component 210. That is, only one of the electronic modules 200A and 200B can be disposed in the accommodation space 130, and the accommodation space 130 cannot be utilized effectively.

As shown in FIG. 5, in the present disclosure, the first electronic components 210 with the larger length and the larger width of the electronic modules 200A and 200B are put upside down relative to each other (herein, being placed reversely along to direction Y), the size of the second electronic component 220 is adjusted to match the size of the first electronic component 210, and the orientation of the electronic module 200A is opposite to the orientation of the electronic module 200B in the vertical direction and in the horizontal direction (herein, parallel to direction X), so that the housing 100 can accommodate the two electronic modules 200A and 200B without increasing the size thereof, which may significantly improve the space utilization efficiency.

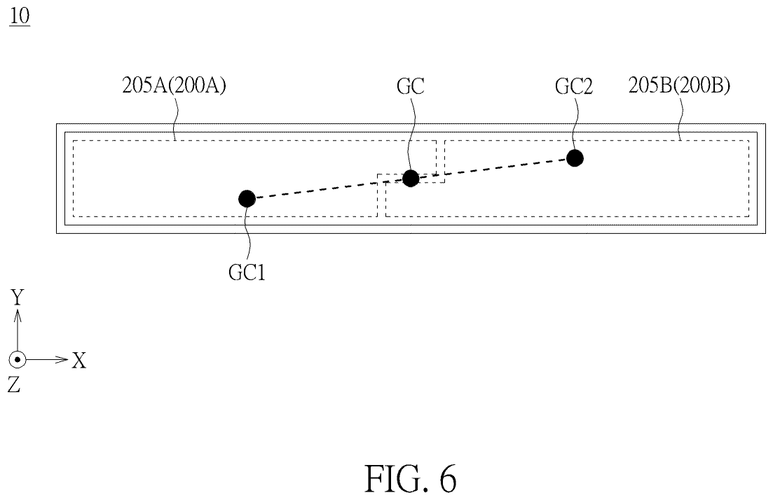

Please refer to FIG. 6, which is a schematic view showing positions of a center of gravity GC of the electronic device 10 and centers of gravity GC1 and GC2 of the two electronic modules 200A and 200B in FIG. 1. In FIG. 6, the electronic module 200A has the center of gravity GC1, and the electronic module 200B has the center of gravity GC2. When the electronic device 10 is placed vertically (that is, the opening of the housing 100 faces upward), with the top and the bottom of the electronic module 200A being placed reversely to that of the electronic module 200B, and the right and the left of the electronic module 200A also being placed reversely to that of electronic module 200B, it is beneficial to allow the center of gravity GC of electronic device 10(also called the center of gravity of the system) close to or located at the geometric center of the electronic device 10, no matter how the positions of the centers of gravity GC1 and GC2 change. The aforementioned geometric center of the electronic device 10 may be the center point CP of the first cross-sectional shape 131 (see FIG. 5).

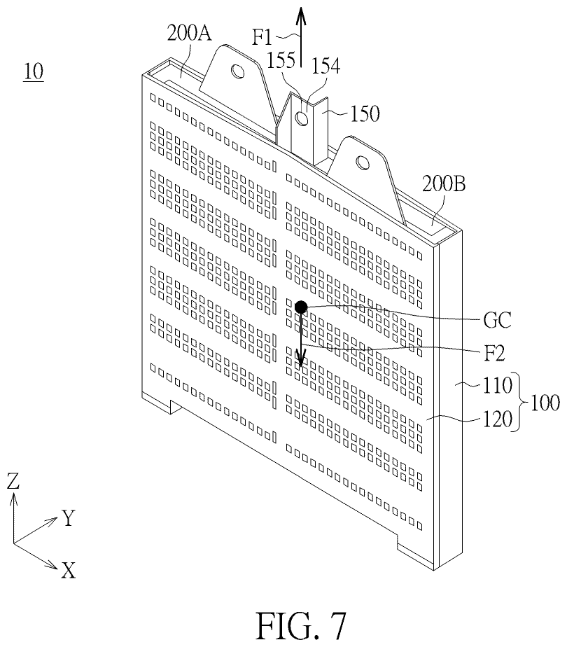

Please refer to FIG. 7, which is a schematic view showing of gravity F2 and a hanging force F1 on the electronic device 10 in FIG. 1. When the electronic device 10 is hung vertically, an upward hanging force F1 can be applied to the electronic device 10 through the hanging hole 155 of the partition 150. The magnitude of the hanging force F1 can be the same as the magnitude of the gravity F2 on the electronic device 10, and the direction of the hanging force F1 may be opposite to the direction of the gravity F2 on the electronic device 10. With the center of gravity GC of the electronic device 10 is close to the geometric center of the electronic device 10, it is beneficial to align the hanging force F1 with the gravity F2 in the vertical direction (parallel to direction Z). Thereby, the hanging stability can be enhanced, and the swing or the deflection of the electronic device 10 occurs when hanging the electronic device 10 can be reduced.

Please refer to FIG. 8, which is a schematic view showing an appearance of an electronic apparatus 1a according to an embodiment of the present disclosure. The electronic apparatus 1a includes at least one the aforementioned electronic device 10 and an installation unit 20. The electronic device 10 is detachably installed in the installation unit 20. In FIG. 8, the electronic apparatus 1a is a liquid-cooled electronic apparatus. The installation unit 20 is a cabinet and can be a liquid cooling tank. The installation unit 20 may include components (not shown) of a typical liquid cooling tank, such as manifolds and heat exchangers. The installation unit 20 may be disposed with a cooling liquid (not shown) therein, the electronic device 10 is immersed in the cooling liquid. The level of the cooling liquid can be adjusted to at least allow the high heat-generating components (such as GPU and CPU) of the electronic device 10 to be immersed in the cooling liquid. With the first housing part 110 of the housing 100 being formed with the heat dissipation holes 111 and the second housing part 120 being formed with the heat dissipation holes 121, it is beneficial for the circulation of cooling liquid inside and outside the housing 100. Thereby, the cooling efficiency of the electronic device 10 can be improved.

In FIG. 8, the Electronic Apparatus 1a Includes a plurality of electronic devices 10, and the plurality of electronic devices 10 can be disposed parallel to each other in the installation unit 20. Although not shown, there may be a spaced distance between any two adjacent electronic devices 10, but not limited thereto. The electronic apparatus 1a can only include one electronic device 10. How to dispose the plurality of electronic devices 10 parallel to each other in the installation unit 20 is well known in the art and are omitted herein.

As shown in FIG. 8, the hanging portions 154 and 206 of the electronic device 10 protrude from the cabinet, but not limited thereto. In some embodiments, the hanging portions 154 and 206 of the electronic device 10 may be lower than the cabinet. The electronic apparatus 1a may be, for example, an immersion cooling system, and the electronic device 10 may be, for example, a blade server, but not limited thereto.

When the electronic device 10 is required to be installed or maintained, the operator can hang the electronic device 10 out from the installation unit 20 along the vertical direction (such as parallel to the direction Z) through the hanging portion 154 for maintenance. With the hanging portion 154, it facilitates moving the electronic device 10 out and into the installation unit 20. Thereby, the convenience of installation and maintenance is improved. With the electronic modules 200A and 200B being arranged oppositely and fitted with each other, it allows the center of gravity GC of the electronic device 10 close to the geometric center, no matter how the positions of the centers of gravity GC1 and GC2 of the individual electronic modules 200A and 200B change. Thereby, the hanging stability can be enhanced. For this part, references may be made to the description related to FIG. 6. In addition, when one of the electronic module 200A and the electronic module 200B requires maintenance, with the hanging portion 206, it is beneficial to solely move the electronic module 200A or the electronic module 200B out or into the installation unit 20 without moving the whole electronic device 10. Therefore, it is labor-saving, and it is favorable for simplifying the maintenance process.

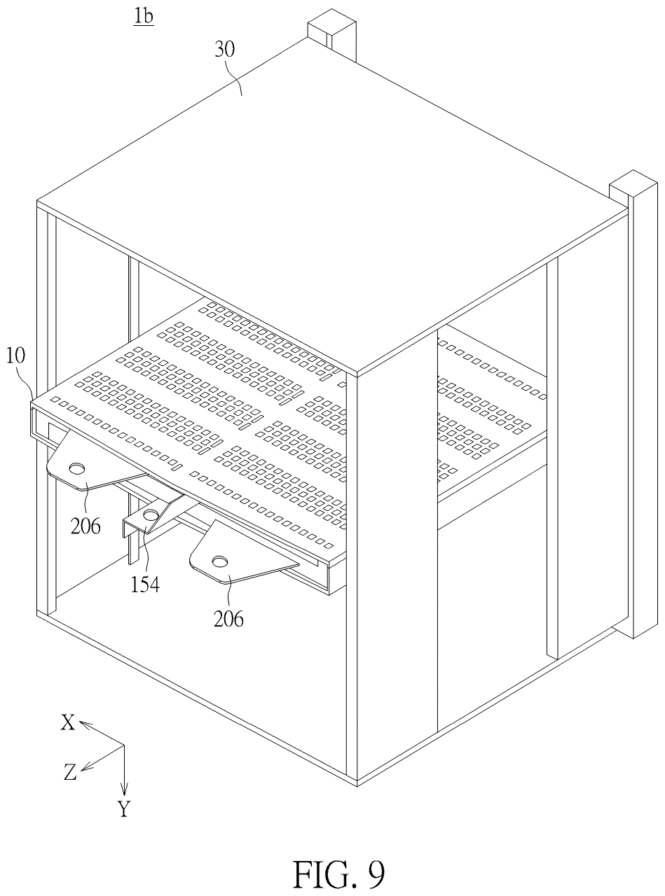

Please refer to FIG. 9, which is a schematic view showing an appearance of an electronic apparatus 1b according to another embodiment of the present disclosure. The electronic apparatus 1b includes at least one the aforementioned electronic device 10 and an installation unit 30. The electronic device 10 is detachably installed in the installation unit 30. In FIG. 9, the electronic apparatus 1b is an air-cooled electronic apparatus, and the installation unit 30 is a rack. The installation unit 30 may optionally include a cooling component (not shown) such as a fan. With the first housing part 110 of the housing 100 being formed with the heat dissipation holes 111 and the second housing part 120 being formed with the heat dissipation holes 121, it is beneficial for the circulation of gas, such as air, inside and outside the housing 100. Thereby, the cooling efficiency of the electronic device 10 can be improved.

In FIG. 9, the electronic apparatus 1b only includes one electronic device 10, but not limited thereto. The electronic apparatus 1b may include a plurality of electronic devices 10 disposed parallel to each other in the installation unit 30. How to dispose the plurality of electronic devices 10 parallel to each other in the installation unit 30 is well known in the art and are omitted herein.

In FIG. 9, the hanging portions 154 and 206 of the electronic device 10 protrude from the rack, but not limited thereto. In some embodiments, the hanging portions 154 and 206 of the electronic device 10 may not protrude from the rack. With the hanging portion 154, it facilitates moving the electronic device 10 out and into the installation unit 30. Thereby, the convenience of installation and maintenance is improved. With the hanging portion 206, it is beneficial to solely move the electronic module 200A or the electronic module 200B out or into the installation unit 30 without moving the whole electronic device 10. Therefore, it is labor-saving, and it is favorable for simplifying the maintenance process.

It should be noted that in FIG. 8, the electronic apparatus 1a is an immersion cooling tank, which is only exemplary. The electronic apparatus 1a according to the present disclosure can be other types of liquid-cooled electronic apparatus, such as a cold plate liquid cooling electronic apparatus. The arrangement of the cold plate liquid cooling electronic apparatus can be the same as that shown in FIG. 9. The cooling component (not shown) can be a cold plate. The types of the electronic apparatuses 1a and 1b according to the present disclosure are not limited.

Compared with the prior art, in the electronic device according to present disclosure, with the second cross-sectional shape formed the by two electronic modules matching the first cross-sectional shape of the housing, it is beneficial to improve the space utilization efficiency of the electronic device.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An electronic device, comprising:
a housing having an accommodation space, wherein the accommodation space has a first cross-sectional shape perpendicular to a first direction; and
two electronic modules disposed in the accommodation space, wherein each of the electronic modules has a concave-convex surface, and the concave-convex surfaces of the two electronic modules are arranged oppositely and cooperate with each other, so that the two electronic modules together form a second cross-sectional shape perpendicular to the first direction, and the second cross-sectional shape matches the first cross-sectional shape.

2. The electronic device of claim 1, wherein the first cross-sectional shape has a first accommodation length in a second direction perpendicular to the first direction, each of the electronic modules has a first length in the second direction, the first length corresponds to a convex portion of the concave-convex surface, the first length is greater than a half of the first accommodation length, and the first length is less than the first accommodation length.

3. The electronic device of claim 2, wherein each of the electronic modules has a second length in the second direction, the second length corresponds to a concave portion of the concave-convex surface, and a sum of the first length and the second length matches the first accommodation length.

4. The electronic device of claim 2, wherein each of the electronic modules comprises a first electronic component and a second electronic component respectively corresponding to the convex portion and a concave portion of the concave-convex surface.

5. The electronic device of claim 4, wherein a length of the first electronic component in the second direction is equal to the first length.

6. The electronic device of claim 4, wherein at least one of the first electronic component and the second electronic component comprises an asymmetric shape.

7. The electronic device of claim 1, wherein the first cross-sectional shape has a second accommodation length in a third direction perpendicular to the first direction, each of the electronic modules has a third length in the third direction, and the third length matches the second accommodation length.

8. The electronic device of claim 7, wherein each of the electronic modules comprises a first electronic component and a second electronic component respectively corresponding to a convex portion and a concave portion of the concave-convex surface, and a length of the first electronic component in the third direction is equal to the third length.

9. The electronic device of claim 8, wherein a length of the second electronic component in the third direction is less than the third length.

10. The electronic device of claim 1, wherein each of the electronic modules comprises a third cross-sectional shape perpendicular to the first direction, and the third cross-sectional shape is an asymmetric shape.

11. The electronic device of claim 1, wherein each of the first cross-sectional shape and the second cross-sectional shape is a rectangle.

12. The electronic device of claim 1, further comprising:
a partition fixed to the housing and disposes between the concave-convex surfaces of the two electronic modules.

13. The electronic device of claim 12, wherein the partition comprises a hanging portion extending to an outside of the accommodation space.

14. The electronic device of claim 12, wherein the partition comprises a first sheet body, a second sheet body and a third sheet body connected in sequence, the first sheet body and the third sheet body respectively correspond to a convex portion and a concave portion of the concave-convex surface of one of the two electronic modules, and the first sheet body and the third sheet body are bent relative to the second sheet body.

15. The electronic device of claim 1, wherein each of the electronic modules is detachably installed in the accommodation space along the first direction.

16. The electronic device of claim 1, wherein each of the electronic modules comprises a hanging portion extending to an outside of the accommodation space.

17. An electronic apparatus, comprising:
the electronic device of claim 1; and
an installation unit, wherein the electronic device is detachably installed in the installation unit.

18. The electronic apparatus of claim 17, wherein the installation unit is a cabinet or a rack.

19. The electronic apparatus of claim 17, wherein the electronic device is detachably installed in the installation unit along the first direction.

20. The electronic apparatus of claim 17, wherein the electronic apparatus is a liquid-cooled electronic apparatus or an air-cooled electronic apparatus.
